(19) United States
(12) Patent Application Publication
(10) Pub. No.: US 2008/0205026 A1
(43) Pub. Date: Aug. 28, 2008

(54) Electromagnetic Compliance Spring of Drive Carrier

(75) Inventors: Pat Gallarelli, Chapel Hill, NC (US); David G. Lund, Byron, MN (US); Michael S. Miller, Raleigh, NC (US); Christopher L. Tuma, Mantorville, MN (US)

Correspondence Address: IBM COPORATION (RTP);C/O SCHUBERT OSTERRIEDER & NICKELSON PLLC, 6013 CANNON MOUNTAIN DRIVE, S14, AUSTIN, TX, 78749, US

(73) Assignee: International Business Machines Corporation, Armonk, NY (US)

(21) Appl. No.: 11/678,881

(22) Filed: Feb. 26, 2007

(51) Int. Cl. H05K 9/00

(52) U.S. Cl. 361/818

(57) ABSTRACT

Systems and arrangements to provide electromagnetic compliance (EMC) for a drive carrier are disclosed. Embodiments may include an EMC spring. The EMC spring may include a shield portion to fasten to one side of a frame of the drive carrier and multiple fingers attached to the shield portion. At least one of the fingers may include an upper spring section to contact an adjoining drive carrier as the drive carrier is inserted into a computing device and a lower spring section. The lower spring section may be folded over against the upper spring section and attached to the shield portion of the spring. The lower spring section may deflect in response to the upper spring section contacting the adjoining drive carrier. In some embodiments, a lead in portion of the upper spring section may deflect to a position nearly parallel to the adjoining drive carrier.

### FIELD

The present invention generally relates to the field of reducing electromagnetic emissions from computing devices. More particularly, the present invention relates to an electromagnetic compliance spring for a drive carrier.

### BACKGROUND

The passage of electrical currents through computing equipment may produce electromagnetic radiation. If not prevented from escaping, this radiation may interfere with standard frequencies used for telecommunications such as the frequencies used for television and cell phones. Accordingly, regulatory agencies, such as the Federal Communications Commission and the International Special Committee on Radio Interference (Comite Internationale Special Preturbation Radioelectrique), require the makers of computing equipment to provide shielding for the electromagnetic radiation. The shielding may reflect or absorb the radiation. Electromagnetic compatibility (EMC) techniques attempt to comply with the regulations.

One type of electromagnetic radiation shield for drives, an EMC spring, may be inserted in a drive carrier. The EMC spring may include a shield with spring fingers extending to the top and bottom of the drive carrier. Advancing technology makes the shielding of drives, such as disk drives, increasingly difficult. The introduction of new disk drive interfaces that operate at very high speeds, such as Serial Attached SCSI, Serial ATA, and Fiberchannel, has forced the disk drive industry to develop new EMC spring designs in order to pass the ever increasing stringency of worldwide regulatory requirements. For example, EMC shielding may be required to be effective at higher frequencies.

The stiffness of many current EMC spring finger designs may cause problems. The basic design may require a substantial force for the insertion of a drive utilizing the spring fingers. A typical EMC spring finger may have a profile similar to a tent, with contact between spring fingers being made where their peaks meet. The result is that a point or linear contact is made. When small point or linear contacts are relied upon, then the forces must be high enough to ensure continuity. The evolution of EMC spring design may continue to increase the insertion force required. When a product fails to meet regulatory requirements, the industry approach has been to stiffen the EMC spring fingers on drive carriers. The carriers may require a larger insertion force, putting stress on the components of a computing system that uses the carriers. With some spring systems, the carriers may require significant insertion forces. When these carriers are installed into systems, their stiff springs may scrape forcefully along the bottom of the disk drives above them, stripping off components or damaging the springs themselves. To solve this problem, metal covers may be installed over the susceptible components. These metal covers, even though perforated, may significantly affect the temperature of the disk drives, causing a degradation of long term reliability of the disk drive.

In addition, many of the designs available on the market cannot provide the EMC performance required on high end servers (over 1 GHz). The few designs that have been designed for the high end server market may not support the tight drive pitch (27.3 mm) that is required to get leading edge drive packaging density (12 drives in 2 U or 16 drives in 3 U expansion boxes). The stiffness of the spring fingers may prevent the spring fingers from compressing sufficiently, without damaging the spring fingers or the components they are in contact with. Further, many EMC springs are susceptible to damage due to insertion of an adjacent drive and general handling. Many EMC springs have sharp edges that pose the risk of cutting their handlers.

### SUMMARY OF THE INVENTION

The problems identified above are in large part addressed by a system, method, and apparatus to provide electromagnetic compliance (EMC) for a drive carrier. Embodiments may include an EMC spring. The EMC spring may include a shield portion to fasten to one side of a frame of the drive carrier and multiple fingers attached to the shield portion. At least one of the fingers may include an upper spring section to contact an adjoining drive carrier as the drive carrier is inserted into a computing device and a lower spring section. The lower spring section may be folded over against the upper spring section and attached to the shield portion of the spring. The lower spring section may deflect in response to the upper spring section contacting the adjoining drive carrier.

Embodiments may include a method to block electromagnetic emissions of a computing device. The method may include fastening a spring finger to a drive carrier, inserting the drive carrier into a drive bay of the computing device, contacting a drive adjoining the drive carrier with an upper section of the spring finger, deflecting a lower spring section of the spring finger in response to the contacting, locking the drive carrier into place, and blocking electromagnetic emissions of the computing device via the spring finger.

### BRIEF DESCRIPTION OF THE DRAWINGS

Advantages of the invention will become apparent upon reading the following detailed description and upon reference to the accompanying drawings in which like references may indicate similar elements:

FIG. 1 depicts an exploded view of an embodiment of a system to provide electromagnetic compliance (EMC) for a drive carrier;

FIG. 2 depicts an assembled isometric view of an embodiment of a drive carrier with generic drive installed;

FIG. 3 depicts a cross section of an embodiment of a spring finger;

FIG. 4A depicts an embodiment of the deflection of a spring finger as a drive carrier is inserted into a drive bay;

FIG. 4B depicts another embodiment of the deflection of a spring finger as a drive carrier is inserted into a drive bay;

FIG. 4C depicts a further embodiment of the deflection of a spring finger as a drive carrier is inserted into a drive bay;

FIG. 5 depicts an embodiment of a drive carrier with an EMC spring;

FIG. 6 depicts an embodiment of the junction between a bezel and spring fingers in a drive carrier;

FIG. 7 depicts an embodiment of a portion of a drive carrier which includes a spring finger with a tapered cutout;

FIG. 8 depicts the contact between spring fingers and adjacent drive carriers when a drive carrier is being inserted into an embodiment of a computing system; and

FIG. 9 depicts a flowchart of an embodiment of a method to block electromagnetic emissions of a computing device.

### DETAILED DESCRIPTION OF EMBODIMENTS

The following is a detailed description of embodiments of the invention depicted in the accompanying drawings. The embodiments are in such detail as to clearly communicate the invention. However, the amount of detail offered is not intended to limit the anticipated variations of embodiments; but on the contrary, the intention is to cover all modifications, equivalents, and alternatives falling within the spirit and scope of the present invention as defined by the appended claims. The detailed descriptions below are designed to make such embodiments obvious to a person of ordinary skill in the art.

Generally speaking, systems, methods, and apparatus to provide electromagnetic compliance (EMC) for a drive carrier are disclosed. Embodiments may include an EMC spring. The EMC spring may include a shield portion to fasten to one side of a frame of the drive carrier and multiple fingers attached to the shield portion. At least one of the fingers may include an upper spring section to contact an adjoining drive carrier as the drive carrier is inserted into a computing device and a lower spring section. The lower spring section may be folded over against the upper spring section and attached to the shield portion of the spring. The lower spring section may deflect in response to the upper spring section contacting the adjoining drive carrier.

In some embodiments, the upper spring section may include a lead out portion, a lead in portion, and a curved peak between the lead out portion and the lead in portion. The lead in portion may slope more gently towards the adjoining carrier than the lead out portion. In further embodiments, the lead in portion may deflect to a position nearly parallel to the adjoining drive carrier in response to the full insertion of the drive carrier into the computing device. In many embodiments, the EMC spring fingers may extend to the reverse side of the frame. A flange on the reverse side may retain the EMC spring fingers. In several embodiments, the surface of the EMC spring fingers lying opposite the shield portion of the spring may be restrained to a tab of a bezel.

Some embodiments of the disclosed apparatus may effectively provide electromagnetic compatibility (EMC) capabilities for hard drive carriers while allowing a low insertion force. Some embodiments of the apparatus may feature narrow gaps between adjoining spring fingers. These embodiments may provide an enhanced EMC shield at frequencies of 1 GHz and above. The EMC capabilities and low insertion force may prove valuable on systems that support hot swapping of drives. On these systems, the drive carrier may act as the primary EMC shield not only for the drive, but also for the system. System operating frequencies have increased significantly. As a result, both the Federal Communications Commission and the International Special Committee on Radio Interference have expanded EMC requirements to frequencies beyond 1 GHz.

In many embodiments of the disclosed apparatus, a relatively low force may suffice to deflect the spring, thereby resulting in low drive insertion force. In further embodiments of the disclosed apparatus, the geometry of the EMC spring fingers may provide a relatively flat area of contact with an adjoining drive. As a result, the geometry may produce a large surface area conductive contact patch. In some further embodiments, the geometry may also prove suitable for a wide range of drive mounting pitches, including but not limited to, narrow drive mounting pitches, such as drive mounting pitches from 26 to 30 mm, from 15 to 20 mm, and other drive mounting pitches.

In several embodiments of the disclosed apparatus, the edges of the EMC spring may be restrained to protect the EMC spring from damage and prevent harm to other components or to handlers from contact with the EMC spring. In a number of embodiments, the EMC spring may contain rounded edges at typical contact points. In some embodiments, protection to the EMC spring, to other components, and to handlers may eliminate the need for a protective cover for the drive components. As a result of the elimination of a protective cover, these embodiments may operate at reduced drive temperatures.

While specific embodiments will be described below with reference to particular circuit or logic configurations, those of skill in the art will realize that embodiments of the present invention may advantageously be implemented with other substantially equivalent configurations.

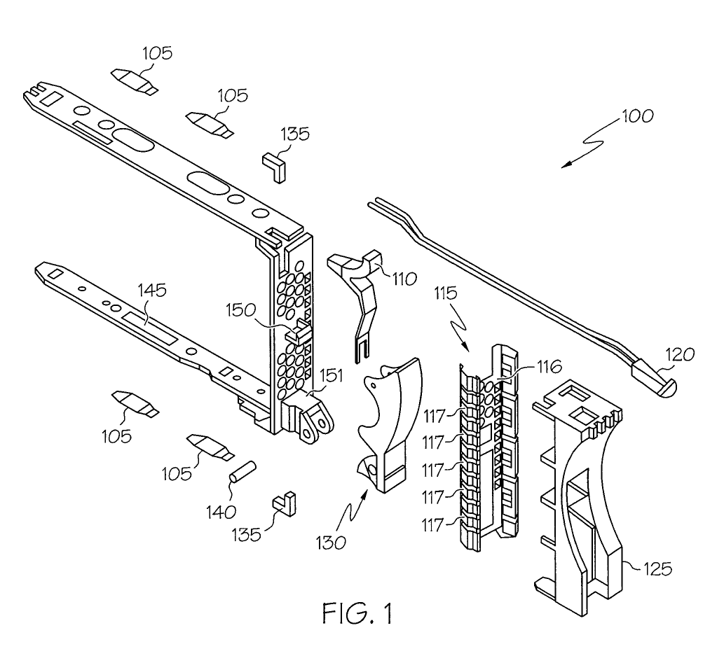

FIG. 1 depicts an exploded view of an embodiment of a system 100 to provide electromagnetic compliance (EMC) for a drive carrier. System 100 may comprise a tray assembly of a drive carrier. System 100 includes a casting 145, an EMC spring 115, a light pipe 120, and fastening elements. The EMC spring 115 may include a ventilated shield portion 116. Sprouting from the shield portion 116 of the EMC spring 115 are spring fingers 117. The fastening elements include a trigger 110, a lever 130, and a bezel 125. The trigger 110 and lever 130 may enable the locking and unlocking of system 100 to a drive bay. The ventilated shield portion 116 of EMC spring 115 may be captured between the front face of the casting 145 and the bezel 125. In some embodiments, the spring fingers 117 may extend to the reverse side of the surface of the casting 145 to which the ventilated shield portion 116 is attached and may be attached to the reverse side of the casting 145. The bezel 125 may be composed of plastic. The light pipe 120 may enable the transmission of light from the back end of the system 100 to the front end. For example, the light pipe 120 may carry light to an activation light, which indicates when the system 100 is connected to a drive bay.

The casting 145 may form the skeleton of the tray assembly 100. The casting 145 may hold a drive, such as a direct access storage device or a removable CD or DVD drive, for insertion into and removal from a drive bay. Elements of the casting 145 include vibration-dampening springs 105, snubbers 135, a roll pin 140, a catch 150 and a pivot block 151. The vibration-dampening springs 105 and snubbers 135 both act to dampen vibrations which might otherwise hinder the performance of a drive. The roll pin 140 may fasten the lever 130 to the pivot block 151 and enable the lever 130 to rotate. A latch of the trigger 110 may hook to the catch 150.

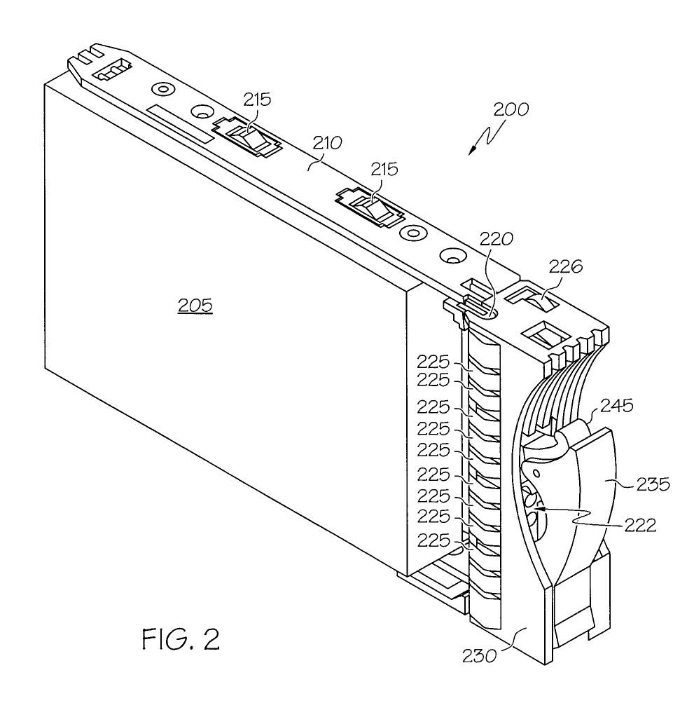

The ventilated shield portion 116 of the EMC spring 115 may provides a ground connection between the EMC spring 115 and the casting 145. In many embodiments, the ventilated shield portion 116 may hold twelve spring fingers 117 on the left and right, in the orientation of the EMC spring 115 shown in FIG. 1. In further embodiments, the shield may hold a spring finger on the top and two spring fingers on the bottom. See upper spring finger 226 of FIG. 2 and upper spring finger 520 of FIG. 5. The upper and lower spring fingers are not depicted in FIG. 1.

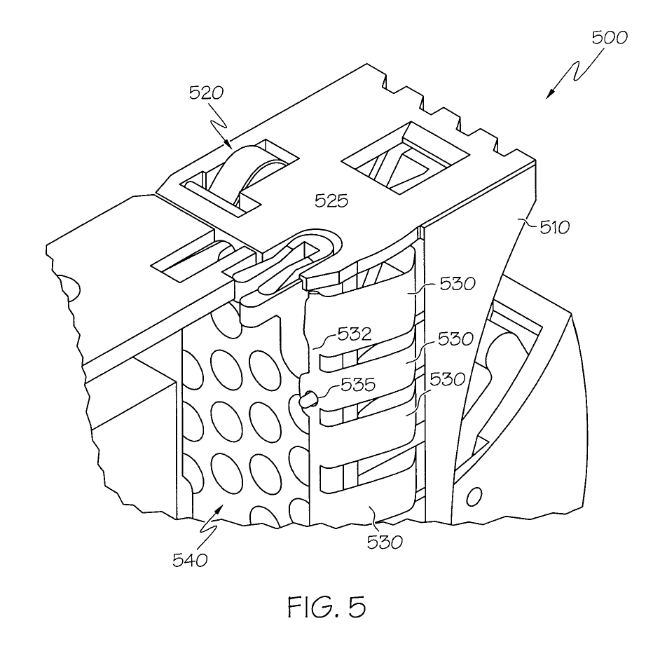

The spring fingers 117 may be fashioned from an electrically conductive material with spring-like characteristics, such as stainless spring steel. The spring fingers may include an upper spring section and a lower spring section. The lower spring section may be folded over against the upper spring section and attached to the shield portion of the spring. The spring fingers 117 may deflect in response to a displacement force, such as when the spring fingers 117 engage a drive carrier adjacent to the system 100. As a drive carrier is inserted adjacent to system 100, the upper spring sections may contact the drive carrier. See FIG. 8 where spring finger 810 of drive carrier 805 may contact drive carrier 823 and spring finger 825 of drive carrier 823 may contact drive carrier 805 as either drive carrier is inserted or removed from computing system 800. The lower spring sections may deflect in response to the upper spring section contacting the adjoining drive carrier. The force of the deflection against contact point on the upper spring sections may cause a mechanical and electrical connection between the spring fingers 117 and the drive carrier of FIG. 1. FIGS. 4A, 4B, and 4C illustrate the deflection of a lower spring section 450 as spring finger 415 contacts block 405.

This deflection and compression may enable the spring fingers 117 of FIG. 1 to serve as dampers for damping encountered shock or vibration of the system 100. The deflection and compression of the spring fingers 117 may also accommodate variable pitch arrangements of multiple carriers.

The EMC spring 115 may block electromagnetic radiation (EMR), both EMR emanating from a drive held by the frame assembly and externally produced EMR traveling towards the drive. For example, a hard drive motor may emit electromagnetic radiation. Additionally, the environment surrounding a hard drive may contain electromagnetic sources. When the frame assembly is inserted into a drive bay, the EMC spring 115 may create an EMR shield in the front of the drive bay chassis slot by filling in a vertical cross-section of the slot. The EMC spring 115 may comprise an electrically conductive metal such as steel. Therefore, when the spring fingers cause an electrical connection with an adjacent drive carrier, the electrical connection may extend generally to the EMC spring 115. An EMC shield with smaller gaps between adjacent spring fingers may shield against higher EMR frequencies. In various embodiments, progressively smaller gaps between adjacent spring fingers and may shield against ever increasing EMR frequencies.

The system 100 is for explanation, not for limitation. In many other embodiments, a different number of vibration dampening springs or snubbers may be used. In a few embodiments, a light pipe may be omitted. In some other embodiments, other mechanisms to lock the system 100 to a drive bay may be utilized.

FIG. 2 depicts an assembled isometric view of an embodiment of a drive carrier 200 with generic drive 205 installed. Drive carrier 200 includes a tray assembly, an EMC spring 222, and a fastening mechanism. The tray assembly includes casting 210, vibration dampening springs 215, and snubber 220.

EMC spring 222 includes spring fingers 225 and spring finger 226. In the orientation of FIG. 2, 12 spring fingers such as spring fingers 225 are shown on the left side of drive carrier 200 and one spring finger 226 is shown on the top of drive carrier 220. In many embodiments, a drive carrier in the orientation of FIG. 2 may also have a symmetric arrangement of spring fingers on the right side. In some embodiments, a drive carrier 200 may include two spring finger on the bottom. The spring fingers may include an upper spring section and a lower spring section. The lower spring section may be folded over against the upper spring section and attached to the shield portion of the spring. The spring fingers 225 and 226 are shown in their uncompressed state.

The spring fingers 225 on the left may contact an adjacent drive or a drive bay. As a drive carrier is inserted adjacent to system 200, the upper spring sections may contact the drive carrier. The lower spring sections may deflect in response to the upper spring sections contacting the adjoining drive carrier. The spring finger 226 on the top may contact a drive bay in which drive carrier 200 is inserted. The fastening mechanism may include a bezel 230, a lever 235, and a trigger 245. The EMC spring 222 may be assembled over the front face of the casting 210 and may be captured between the bezel 230 and the casting 210.

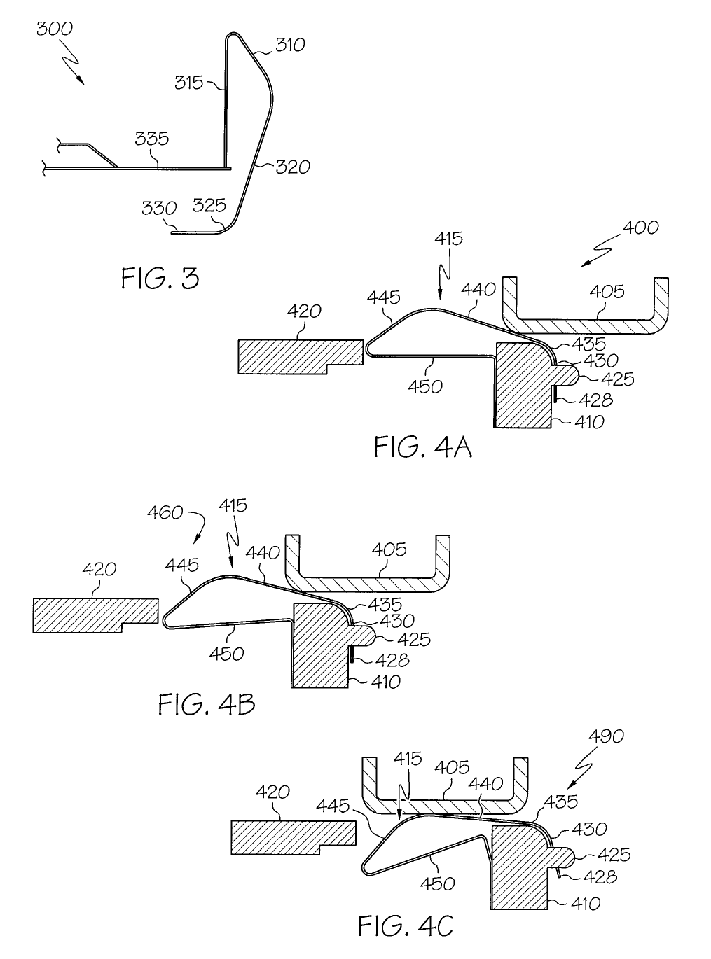

Turning to FIG. 3, depicted is a cross section of an embodiment of an EMC spring 300. The spring cross section 300 includes a ventilated shield 335, a lower spring finger section 315, an upper spring finger section, a curved section 325, and a retention flange 330. The upper spring finger section consists of the lead-out ramp 310 and the lead-in ramp 320. In the embodiment of FIG. 3, the lower spring finger section 315 doubles over to form the upper spring finger section. The double sections may behave as springs in series. Series springs allow for greater deflections at a lower force. In some embodiments, the double section design may enable a nominal spring force of between 7 and 10 lbs. In several embodiments, the deflections produced by spring finger may be designed to allow hot swap drives to be mounted in systems that have centerline spacing of 27.3 mm or 29.1 mm. In other embodiments, the deflections may allow the mounting of drive carriers with other centerline spacings, such as 26 to 30 mm, 15 to 20 mm, etc.

Lead-in ramp 320 slants towards an adjacent drive at a more gradual angle than lead-out ramp 310. The insertion of a drive carrier containing EMC spring 300 into a drive bay may cause lead-in ramp 320 to come in contact with an adjacent drive and deflect. The deflection may cause a deflection in the lower spring finger section 315. In some embodiments, the gradual angle of the lead in ramp 320 may reduce the chance that a component will be knocked off when the drive carrier is inserted or an adjacent drive is removed.

Beyond the lead-in ramp 320 is a curved section 325. The curved section 325 may extend beyond the shield portion 335 of EMC spring 300 to a casting. The curved section 325 may protect the EMC spring 300 and handlers of the spring. Handlers may grasp the drive carrier containing EMC spring 300 near the casting and accidentally come into contact with curved section 325. The curved shape may prevent cutting the handler or damaging the EMC spring 300. Following curved section 325 is a retention flange 330. In some embodiments, pins may restrain retention flange 330 to a casting. The fastening may prevent damage to the EMC spring 300.

FIGS. 4A, 4B, and 4C depict stages in the deflection of a spring finger of an embodiment of a drive carrier as the drive carrier is inserted into a drive bay from left to right. Systems 400 in FIG. 4A, 460 in FIG. 4B, and 490 in FIG. 4C include a drive carrier and a block 405. Block 405 could represent the drive bay in which the drive carrier is inserted or an adjacent drive carrier. The drive carrier includes a bezel 420, a spring finger 415, and a casting 410. The spring finger 415 includes a hole support 428, a retention flange 430, a curve 435, an upper spring section which includes a lead-in ramp 440 and a lead-out ramp 445, and a lower spring section 450. The block 405 may represent a sheet metal piece of an adjacent drive carrier or carrier bay. Casting 410 includes pin 425. Pin 425 may protrude through a hole in the retention flange 430 to restrain spring finger 415 to casting 410. In the drawings, the hole is represented in cross section as a gap between retention flange 430 and hole support 428. In other embodiments, an edge of a spring finger may insert into a slot in a casting to secure the spring finger to the casting.

In the stage of insertion of FIG. 4A, the spring finger 415 may barely contact the block 405, at a point on lead-in ramp 440. Spring finger 415 is in its uncompressed state. In the orientation of FIG. 4A, the lower spring section 450 is roughly horizontal, and the lead-out ramp 445 and lead-in ramp 440 are positioned at an angle to the longitudinal axis of block 405. The spring finger 415 fits snugly against the left face of the casting 410.

In FIG. 4B, the contact with drive carrier block 405 may deflect the upper spring section and lower spring section 450 of spring finger 415 downwards in comparison with the orientation of the spring sections in FIG. A. For example, in the orientation of FIG. 4B, the lower spring section 450 is slanted downward.

In FIG. 4C, maximum deflection of the spring finger 415 may have occurred. In the orientation of FIG. 4C, the lower spring section 450 is sharply angled downward and the end near the casting 410 has pulled away from the casting. In some embodiments of an EMC spring, a bezel may hold the EMC spring in place against the casting even when the spring fingers are at maximum deflection. In FIG. 4C, the lead-in ramp 440 is almost horizontal, providing good contact with block 405.

The deflection illustrated by FIGS. 4A, 4B, and 4C may enable use of a much smaller insertion force and removal force for the drive carrier in the systems (400, 460, 490) than a typical design of an EMC spring, while providing a larger surface area of contact for conduction and reducing the risk of damage to components. A typical EMC spring finger has profile similar to a tent with contact between spring fingers being made where their peaks meet. The result is that a point or linear contact is made. When small point or linear contacts are relied upon, then the normal force pushing the contacts together must be high enough to ensure continuity. The force may be in the range of 30 to 35 lbs., and the force required to insert the drive carrier may be correspondingly high. In addition, the relatively sharp contact point may create a risk of the spring damaging components on the drive above it.

In contrast, the geometry of the spring fingers in FIGS. 4A, 4B, and 4C may feature a peak with a more gradual radius, because the spring sections may be longer than in the typical design. As the front nose of the spring is deflected down, the flat lead in ramp rotates to near parallel to the top surface of the casting. As a result, adjacent springs lay upon each other flat section to flat section when deflected. This geometry thus creates a significantly larger surface area to create conduction between EMC springs on adjacent drives. The more rounded peak also reduces the risk of a spring damaging components on the drive above it. Further, the normal force needed to fully deflect the spring finger may be reduced to 7 to 10 lbs., and the insertion force may be correspondingly reduced.

Turning now to FIG. 5, depicted is an embodiment of a drive carrier 500 with an EMC spring. Drive carrier 500 includes a bezel 510, an upper spring finger 520, a snubber 525, spring fingers 530, a flange 532, a pin 535, and a casting 540. The casting 540 may form a portion of the frame of the drive carrier 500. The portion of the spring fingers 530 visible in FIG. 5 may include an upper spring section to contact an adjoining drive carrier as the drive carrier 500 is inserted into a drive bay of a computing device. The spring fingers 530 may also include a lower spring section, not visible in FIG. 5, folded over against the upper spring section and attached to the shield portion of the spring. The lower spring section may deflect in response to the upper spring section contacting the adjoining drive carrier.

The design of the spring fingers 530 in FIG. 5 may protect the spring fingers 530 from damage and may protect users against cuts during handling. Users often use the area of the casting 540 where the spring fingers 530 terminate as a handle. In the embodiment of FIG. 5, the trailing edge of the spring fingers 530 has a generous radius that curves over the casting 540 to the rear face of the casting 540, where the spring fingers join to form a flange 532. The shield portion of the spring may be attached to the front face of the casting 540, not visible in FIG. 5. Pins, such as pin 535, located on the casting 540 may protrude through holes in the flange 532. The pins, such as pin 535, may permit the spring fingers 530 to deflect but may be sufficiently long to prevent the spring fingers 530 from slipping over the pins in normal operation. In some embodiments, the pins may be conically shaped. Wrapping the spring fingers 530 with the flange 532 and securing the spring fingers 530 with pins such as pin 535 protruding through holes in the flange 532 may prevent a user from inadvertently pulling up on the spring fingers 530, causing damage. The wrapping also isolates the sharp edges of the spring fingers 530 to prevent cutting the user. The pins such as pin 535 also prevent the spring fingers 530 from lifting up during severe deflection. In other embodiments, a flange discrete from the spring fingers may restrain the spring fingers against the casting.

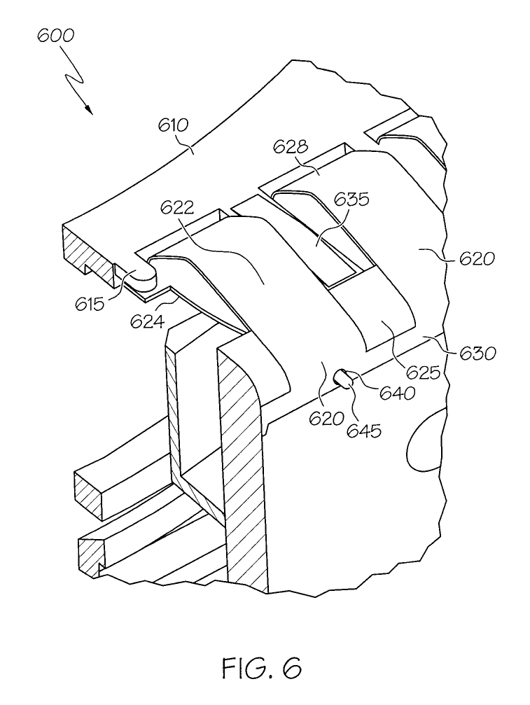

FIG. 6 depicts the junction between a bezel 610 and spring fingers 620 in an embodiment of a drive carrier 600. The drive carrier 600 also includes a casting 625. The spring fingers 620 include an upper spring section such as upper spring section 622 to contact an adjoining drive carrier as the drive carrier 600 is inserted into a drive bay of a computing device. The trailing edges of the upper spring sections such as join to form flange 630. The spring fingers 620 also include a lower spring section such as lower spring section 624, folded over against the upper spring section 622 of spring finger 620 and attached to the shield portion of an EMC spring which includes the spring finger 620. The lower spring section 624 may deflect in response to the upper spring section 622 contacting the adjoining drive carrier.

Bezel 610 includes bezel tab 615 and guard 635. A bezel tab 615 may hold in the front portion 628 of a spring finger 620, the portion of a spring finger 620 opposite the casting 625, where the upper and lower spring sections (622, 624) meet. A bezel tab 615 may thereby protect the spring finger 620. Absent bezel tab 615, the insertion of a drive case adjacent to the spring fingers 620 at an angle may cause the drive's connector to protrude below the spring fingers 620. The contact may pull the front of the spring fingers 620 out of the protective bezel 610 and damage the spring fingers. The bezel tabs 615 may trap the front 628 of the spring fingers 620, preventing the front from lifting above the surface of the bezel. Bezel guard 635 may be moon-shaped and may extend near the top surface of casting 625 in the orientation of FIG. 6. Bezel guard 635 may prevent the over-deflection of a spring finger 620 by stopping the downward movement of an object depressing the spring fingers 620.

The flange 630 may contain holes such as hole 640. Pins such as pin 645 on the surface of casting 625 may protrude through the holes such as hole 640 to restrain flange 630 against casting 625. The combination of pins on the rear face of the casting 625 and the tabs 615 in the bezel 610 may protect the spring fingers 620 from being dislodged and damaged.

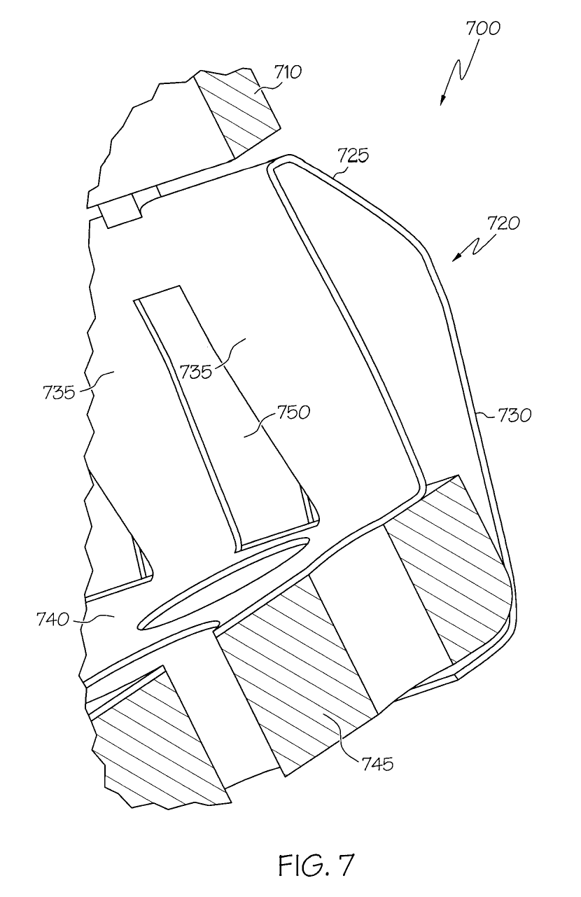

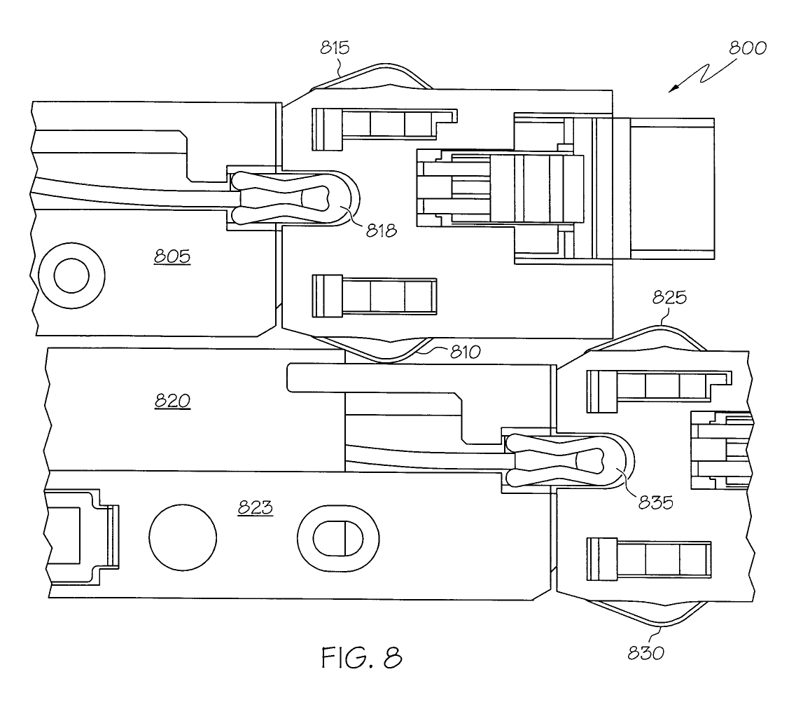

Turning to FIG. 7, depicted is an embodiment of a portion of a drive carrier 700 which includes a spring finger with a tapered cutout. Drive carrier 700 includes a bezel 710, a spring 720, and a casting 745. Spring 720 includes lead-out ramp 725, lead-in ramp 730, lower spring section 735, and ventilated shield 740. Lead-out ramp 725 and lead-in ramp 730 may comprise an upper spring section. Lower spring section 735 is folded over against the upper spring section and attached to ventilated shield 740. Lower spring section 735 includes tapered cutout 750. The upper spring section may contact an adjoining drive carrier as the drive carrier 700 is inserted into a drive bay of a computing device. Lower spring section 735 may deflect in response to the upper spring section contacting the adjoining drive carrier.

Varying the shape of the tapered cutout, such as cutout 750 in FIG. 7, may provide a method to tune the force needed to deflect an EMC spring, such as spring 720, to permit insertion of a drive in an adjoining slot without causing component damage. The tuning may enable optimizing EMC performance while minimizing insertion forces. Because the spacing between adjacent slots may vary in different computing devices, the deflection required for insertion of a drive into a computing device may vary. A typical deflection range of the spring fingers is 40% d to 60% d based on a 2.3 mm spring height, where d represents the full height of an undeflected spring. The spring height is for illustration and not limitation. In many embodiments, the EMC may have heights other than 2.3 mm.

Increasing the size of a cutout may reduce the force required to produce a given deflection, thereby enabling the insertion of a drive with a smaller force. The maximum width of a cutout may be larger than the maximum gap between the upper spring sections of adjacent spring fingers. The upper spring sections provide EMR confinement by making contact at the back of the lead in ramp with the casting. A small maximum gap, often in the 4 mm range, may be necessary to confine radiation with a frequency beyond 1 GHz. Since the lower spring sections are outside of the EMR contain area, there is no similar limitation on the width of the cutouts.

FIG. 8 depicts the contact between spring fingers of a drive carrier and an adjacent drive carrier when a drive carrier is inserted into an embodiment of a computing system 800. Computing system 800 includes a pair of adjacent drive carriers (805 and 823). Carrier 805 includes spring finger 810, spring finger 815, and snubber 818. Carrier 823 includes drive 820, spring finger 825, spring finger 830, and snubber 835. In addition to providing damping, the purpose of the snubbers such as snubber 835 is to vertically control the location of a drive carrier, thereby controlling spring deflection.

The spring fingers (810, 815, 825, 830) of a drive carrier (805 or 823) may contact an adjoining drive carrier as the drive carrier or the adjoining drive carrier is inserted into a drive bay of computing system 800. For example, spring finger 810 of drive carrier 805 may contact drive carrier 823 and spring finger 825 of drive carrier 823 may contact drive carrier 805 as either drive carrier is inserted or removed from computing system 800. The spring fingers (810, 815, 825, 830) may include lower spring sections, folded over against the upper spring sections of the spring fingers and attached to the shield portions of EMC springs which include the spring fingers (810, 815, 825, 830). The lower spring sections may deflect in response to the upper spring sections contacting the adjoining drive carrier. The shape of the spring fingers (810, 815, 825, 830) in FIG. 8 may provide a gentle ramp to allow for a low force insertion of a drive carrier (805, 823) without damaging components on an adjacent drive.

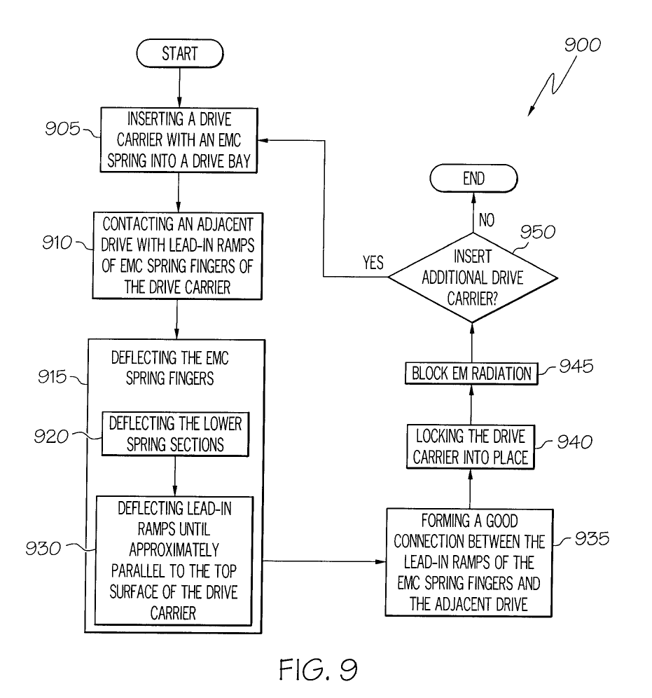

Turning to FIG. 9, depicted is a flowchart 900 of an embodiment of a method to block electromagnetic emissions of a computing device. Flowchart 900 begins with inserting a drive carrier with an EMC spring into a drive bay of the computing device (element 905). The EMC spring may include spring fingers divided into upper and lower spring sections. The upper and lower spring sections may be folded together. An upper spring section may include a lead-out ramp and a lead-in ramp which join together to form a gently rounded peak.

As the drive carrier is inserted into the drive bay, the spring fingers may contact an adjacent drive or an adjacent drive bay. The initial contact may be made by the lead-in ramps (element 910) of the upper spring section. The contact with the adjacent ramp may deflect the EMC spring fingers (element 915). The deflecting may include a deflecting of the lower spring sections (element 920). As the insertion of the drive carrier continues, the lead-in ramps may deflect until they are nearly parallel to the top surface of the adjoining drive carrier (element 930). The lead-in ramps may contact spring fingers of the adjoining drive carrier. The positioning of the lead-in ramps parallel to the adjoining drive carrier may provide a large contact surface with the adjoining drive carrier (element 935), forming a good connection for the conduction of electric current.

Flowchart 900 may include locking the drive carrier into place (element 940). A lever at the end of the drive carrier may rotate against the drive carrier, and a trigger may engage. The EMC spring of the drive carrier may block EMR emanating from and moving towards the drive (element 945). The EMC spring may be formed from steel or another conductive substance, and may fill the empty space of a vertical cross section of the drive carrier. The fingers may establish a ground connection with adjoining drives.

If there are additional drive carriers to be inserted in the computing device (element 950), elements 905 through 945 may be repeated. If there are no additional drive carriers to be inserted, the method of flowchart 900 may end.

The elements of flowchart 900 are for illustration and not for limitation. In alternative embodiments, some of the elements of flowchart 900 may be omitted or others may be added. For example, in some other embodiments, because of the geometry of a spring finger, the portion coming into contact with an adjacent drive or a carrier bay may not be parallel to the adjacent drive. In many other embodiments, a drive carrier may have one or more spring fingers on the top or bottom which contact the drive bay into which the drive carrier is inserted.

It will be apparent to those skilled in the art having the benefit of this disclosure that the present invention contemplates a system, method, and apparatus to provide electromagnetic compliance for a drive carrier. It is understood that the forms of the invention shown and described in the detailed description and the drawings are to be taken merely as examples. It is intended that the following claims be interpreted broadly to embrace all the variations of the example embodiments disclosed.

While certain operations have been described herein relative to a direction such as “above” or “below” or “left” or “right” it will be understood that the descriptors are relative and that they may be reversed or otherwise changed if the relevant structure(s) were inverted or moved. Therefore, these terms are not intended to be limiting.

Although the present invention and some of its advantages have been described in detail for some embodiments, it should be understood that various changes, substitutions and alterations can be made herein without departing from the spirit and scope of the invention as defined by the appended claims. Although an embodiment of the invention may achieve multiple objectives, not every embodiment falling within the scope of the attached claims will achieve every objective. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A spring to provide electromagnetic compliance for a drive carrier, the spring comprising:
a shield portion to fasten to one side of a frame of the drive carrier; and
a plurality of fingers attached to the shield portion; wherein at least one finger of the plurality of fingers comprises:
an upper spring section to contact an adjoining drive carrier as the drive carrier is inserted into a drive bay of a computing device; and
a lower spring section folded over against the upper spring section and attached to the shield portion, the lower spring section adapted to deflect in response to the upper spring section contacting the adjoining drive carrier.

2. The spring of claim 1, wherein:
two or more of the plurality of the spring fingers are oriented to extend to the reverse side of the one side of the frame; and
the two or more of the plurality of fingers comprise a flange to be oriented longitudinally on the reverse side of the one side of the frame and to be restrained against the reverse side of the one side of the frame.

3. The spring of claim 2, further comprising a conical pin to restrain the flange to the reverse side of the one side of the frame.

4. The spring of claim 1, wherein the upper spring section comprises:
a lead out portion with a steeper angle toward the adjoining drive carrier;
a lead in portion with a more gradual angle toward the adjoining drive carrier; and
a curved peak between the lead out portion and the lead in portion.

5. The spring of claim 4, wherein the lead in portion is adapted to deflect to a position nearly parallel to the adjoining drive carrier in response to the full insertion of the drive carrier into the computing device.

6. The spring of claim 1, wherein a surface of the at least one finger of the plurality of fingers, the surface oriented to lie opposite the shield portion of the spring, is adapted to be secured by a tab of a bezel.

7. The spring of claim 1, wherein the lower spring section includes a tapered cutout.

8. The spring of claim 1, wherein:
the plurality of fingers is arranged laterally along two opposing vertical sides of the shield; and
the maximum gap between two adjoining fingers of the plurality of fingers, the two adjoining fingers arranged along the same one of the two opposing vertical sides, is adapted to block electromagnetic radiation of frequencies of 1 GHz and higher.

9. A system to provide electromagnetic compliance (EMC) for a drive carrier, the system comprising:
a casting of the drive carrier; and
an EMC spring, the EMC spring comprising:
a shield portion to fasten to one side of a surface of the casting; and
a plurality of fingers attached to the shield portion; wherein at least one finger of the plurality of fingers comprises:
an upper spring section to contact an adjoining drive carrier as the drive carrier is inserted into a drive bay of a computing device; and
a lower spring section folded over against the upper spring section and attached to the shield portion, the lower spring section adapted to deflect in response to the upper spring section contacting the adjoining drive carrier.

10. The system of claim 9, the system comprising a flange, the flange oriented longitudinally on the reverse side of the one side of the surface of the casting, the flange restraining the plurality of fingers to the casting.

11. The system of claim 9, the system comprising a bezel to hold in the shield portion, the bezel comprising a tab to restrain a surface of the at least one finger of the plurality of fingers to a portion of the bezel.

12. The system of claim 11, the bezel comprising a guard to limit the deflection of the at least one finger of the plurality of fingers.

13. The system of claim 9, the system comprising one or more spring fingers to contact the drive bay of the computing device on the insertion of the drive carrier into the drive bay.

14. The system of claim 9, wherein the upper spring section comprises:
a lead out portion with a steeper angle toward the adjoining drive carrier;
a lead in portion with a more gradual angle toward the adjoining drive carrier; and
a curved peak between the lead out portion and the lead in portion.

15. The system of claim 13, wherein the lead in portion is adapted to deflect to a position nearly parallel to the adjoining drive carrier in response to the full insertion of the drive carrier into the drive bay.

16. The system of claim 9, wherein the lower spring section includes a tapered cutout.

17. A method to block electromagnetic emissions of a computing device, the method comprising:
fastening a spring to a drive carrier, the spring comprising a spring finger;
inserting the drive carrier into a drive bay of the computing device;
contacting a drive adjoining the drive carrier with an upper section of the spring finger;
deflecting a lower spring section of the spring finger in response to the contacting;
locking the drive carrier into place; and
blocking electromagnetic emissions of the computing device via the spring finger.

18. The method of claim 17, further comprising deflecting an upper section of the spring finger until a lead in portion of the upper section is nearly parallel with the drive adjoining the drive carrier.

19. The method of claim 17, wherein:
the spring finger is attached to a spring shield;
the spring shield is attached to one side of a surface of a casting of the drive carrier; and
the fastening includes restraining the spring finger with a flange oriented longitudinally on the reverse side of the surface of the casting.

20. The method of claim 17, further comprising restraining the spring finger via a tab of a bezel of the drive carrier.
